(19) United States
(12) Patent Application Publication
(10) Pub. No.: US 2020/0305310 A1
(43) Pub. Date: Sep. 24, 2020

(54) RACK MOUNTABLE IMMERSION COOLING ENCLOSURES

(71) Applicant: Microsoft Technology Licensing, LLC, Redmond, WA (US)

(72) Inventors: Husam Alissa, Redmond, WA (US); Nicholas Keehn, Kirkland, WA (US)

(21) Appl. No.: 16/362,229

(22) Filed: Mar. 22, 2019

(51) Int. Cl. H05K 7/20

(52) U.S. Cl. CPC H05K 7/20809; H05K 7/203; H05K 7/20381; H05K 7/20281; H05K 7/20772; H05K 7/20236; H05K 7/20836

(57) ABSTRACT

Rack mountable immersion cooling enclosures and associated computing facilities are disclosed herein.

### BACKGROUND

Large computing facilities such as datacenters typically include a distributed computing system housed in large buildings, containers, or other suitable enclosures. The distributed computing system can contain thousands to millions of servers interconnected by routers, switches, bridges, and other network devices. The individual servers can host one or more virtual machines or other types of virtualized components. The virtual machines can execute applications to provide cloud or other suitable types of computing services to users.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Servers in datacenters typically include one or more central processing units (“CPUs”), graphic processing units (“GPUs”), solid state drivers (“SSDs”), memory chips, etc. mounted on a printed circuit board as a “server blade.” CPUs, GPUs, and other components of a server blade can produce heat during operation. If not adequately dissipated, the produced heat can damage and/or degrade performance of the various components on the server blade.

Various techniques using air cooling have been developed to dissipate heat produced by components of servers. For example, one technique includes placing a fan in a server enclosure (e.g., top or bottom of a cabinet) to force cool air from outside of the server enclosure into contact with heat producing components on server blades and carry away heat to the outside of the server enclosure. In another example, intercoolers (e.g., cooling coils) can be positioned between sections of server blades in the server enclosure. The intercoolers can remove heat from sections of the servers in a server enclosure and generally maintain the cooling air at a certain temperature range inside the server enclosure.

The foregoing air cooling techniques, however, have certain drawbacks. First, air cooling can be thermodynamically inefficient when compared to liquid cooling. Heat transfer coefficients of conduction and/or convection with air as a heat transfer medium can be an order of magnitude below with water, ethylene glycol, or other suitable types liquid. As such, due to limitation on heat removal, densities of heat producing components (e.g., CPUs and GPUs) on a server motherboard can be limited. In addition, air cooling can have long lag times in response to a control adjustment and/or load change. For example, when a server enclosure has a temperature exceeds a threshold, additional flow of cooling air can be introduced into the server enclosure to reduce the temperature. However, due to slow thermal transfer rates of cooling air, the temperature in the server enclosure may stay above the threshold for quite a long time.

Immersion cooling techniques can address at least some of the foregoing drawbacks of air cooling. Immersion cooling generally refers to a cooling technique according to which components such as CPUs, GPUs, SSDs, memory, and/or other electronics components of a server are submerged in a thermally conductive but dielectric liquid (referred to herein as a “dielectric coolant”). Example dielectrics coolants can include mineral-oils or synthetic chemicals. Such dielectric coolants can have dielectric constants similar to that of ambient air. For example, a dielectric coolant provided by 3M (Electronic Liquid FC-3284) has a dielectric constant of 1.86 while that of ambient air at 25° C. is about 1.0.

In certain implementations, during operation, the dielectric coolant can remove heat from the heat producing components via evaporation by partially transforming into a dielectric vapor, and thus forming a two-phase fluid in a server enclosure. The dielectric vapor in the two-phase fluid can then be cooled and condensed via a circulation system employing liquid pumps, heat exchangers, dry coolers, etc. to reject heat from the dielectric coolant. In other implementations, the dielectric coolant can stay in a single-phase during operation. Due to high heat transfer coefficients of using the dielectric coolant, densities of heat producing components in a server enclosure may be increased. Higher densities of CPUs, GPUs, etc. can result in smaller footprint for datacenters, racks, server enclosures, or other suitable types of computing facilities. High heat transfer coefficients of using the dielectric coolant can also allow fast cool down of sever components in a server enclosure.

One example design of an immersion cooling enclosure includes an elongated container (e.g., a 10-foot long container commonly referred to as a “tank”) housing multiple server blades mounted vertically in the tank. Such a design has several drawbacks. First, retrofitting tank-type immersion cooling enclosures into support structures of an existing datacenter may be difficult or even impossible. In example datacenters, server blades are typically installed in racks, cabinets, drawers, or other supporting structures have certain height, width, or depth dimensions. Such dimensions typically cannot accommodate such large tanks.

Also, such a tank design can incur high operating costs due to loss of a dielectric coolant used in the tank. During operation, dielectric coolant can be lost from an immersion cooling enclosure due to leakage, pressure control, maintenance, or other reasons. For example, pressure inside the tank may exceed a threshold level during operation. To reduce the pressure, a portion of the dielectric coolant may be purged from the tank. In another example, when one of the server blades in the tank fails, a technician may need to open the tank housing all the server blades to replace the failed server blade. In addition, current datacenters can have relatively high air velocity due to implementation of existing air cooling. The high air velocity can further exacerbate loss of the dielectric coolant due to leakage, pressure control, etc.

Several embodiments of the disclosed technology can address at least some of the drawbacks of the tank design by implementing a rack mountable immersion cooling enclosure configured to house one or more server blade. In one embodiment, the immersion cooling enclosure can be configured to accommodate a single server blade. In another embodiment, the immersion cooling enclosure can be configured to accommodate two or more portions of a server blade juxtaposed to one another. In further embodiments, the immersion cooling enclosure can be configured to accommodate two or more server blades.

In certain implementations, the immersion cooling enclosure can include a polyhedron or cuboid shape having a top wall, a bottom wall, and sidewalls between the top and bottom walls forming an interior space. The sidewalls of the immersion cooling enclosure can have a height, width, and/or depth selected to fit into existing rack, drawer, or other suitable types of support structures. In other implementations, the immersion cooling enclosure can also have trapezohedron or other suitable shapes.

In one embodiment, a server blade can be mounted on the bottom wall in the interior space of the immersion cooling enclosure. The server blade can include a PCB carrying one or more CPUs, GPUs, SSDs, memory chips, or other suitable types of components. The PCB and the components carried on the PCB can be submerged in a dielectric coolant inside the immersion cooling enclosure. The PCB of the server blade can be oriented generally perpendicular to gravity when installed into an existing rack, drawer, or other suitable types of support structures. A distance between the top wall and the bottom wall (referred to as “spacing”) can be just sufficient to accommodate a height of the PCB and components carried thereon. For example, the spacing can be about 105% of a largest height of the components on the PCB extending from the bottom wall toward the top wall. In other examples, the spacing can be 110%, 115%, 120%, or other suitable values not exceeding 150%, 200%, or 250%.

The top wall of the immersion cooling structure can include a cooling element attached to or embedded in. For example, the top wall can include a heat exchanger (e.g., a cooling coil) attached to the top wall. In another example, the top wall can include a cooling coil embedded in an internal space of the top wall. In yet another example, the top wall can include a generally hollow internal space having optional baffles, diffusers, etc., to allow a coolant to flow through. In further examples, the top wall can also include a thermoelectric cooler (e.g., a Peltier cooler) and/or other suitable types of cooling elements.

In operation, heat generated by various components of the server blade can evaporate a portion of the dielectric coolant submerging the server blade. The evaporated dielectric coolant moves upward as vapor toward the top wall as a vapor in the interior space of the immersion cooling enclosure. Cooling fluid (or chilled water or other suitable types of coolant) flowing through the top wall can then remove heat from and condense the vapor into a liquid form. The condensed dielectric coolant can then return toward the server blade due to gravity. The cooling fluid can then be collected, and waste heat ejected in a heat exchanger (e.g., a cooling tower) at a rack level, a row level, a datacenter level, or other suitable facility level.

Several embodiments of the immersion cooling enclosure have certain advantages when compared to the tank design of immersion cooling. For example, server blades housed in the immersion cooling enclosures can be co-located with other air-cooled server blades in a single rack, drawer, etc. Also, pressure control, fluid expansion, and dielectric coolant condensing can all be server-level serviceable, and thus reducing large scale downtime. In contrast, when one server blade fails in a tank, other server blades may be shut down before the failed server blade can be serviced. In addition, the immersion cooling enclosure can be configured to contain a small volume of the dielectric coolant. As such, risks of excessive pressure buildup can be at least reduced when compared to a larger and deeper tank. Thus, risks of catastrophic tank-level failure may be reduced. In another example, the immersion cooling enclosures can be pre-filled on-site for quick swapping or left empty for ease of transport. Such a flexibility is not available to the tank design.

In certain embodiments, one or more of the top wall, the bottom wall, or sidewalls can also optionally include a purge port, a refill port, and/or a pressure control port. The purge port can be configured to purge the dielectric coolant from the immersion cooling enclosure during, for instance, a maintenance operation. The refill port can be configured to refill the interior space of the immersion cooling enclosure with additional dielectric coolant. The pressure control port can be configured to allow a pressure control valve (or other suitable devices) to control a pressure inside the immersion cooling enclosure by venting a portion of the dielectric coolant from the immersion cooling enclosure. In other embodiments, one or more of the foregoing ports may be omitted and/or combined. For instance, the pressure control port may be combined with the purge port in some designs. In further embodiments, the immersion cooling enclosure can also include a level control port and/or other suitable types of port.

In other embodiments, one or more components of a server blade may be positioned outside of the immersion cooling enclosure. For example, hard disk drives (“HDDs”), which can be sensitive to pressure may be positioned outside of the immersion cooling enclosure to be air cooled. Connection between the HDDs and other components of the server blade may be established via connector(s) on one or more of the top wall, bottom wall, or sidewalls of the immersion cooling enclosure. In other embodiments, the immersion cooling enclosure can also include or be coupled to a fluid level detection system that is configured to autonomously fill and purge the dielectric coolant. An example of such a fluid level detection system can include a float (or other suitable level sensor) operatively coupled to a valve configured to introduce additional dielectric coolant into the immersion cooling enclosure. Such as fluid level detection system can also act be configured as a leak and/or tilt detection system.

### BRIEF DESCRIPTION OF THE DRAWINGS

FIG. 1 is a schematic diagram of a computing facility having rack mountable immersion cooling enclosures configured in accordance with embodiments of the disclosed technology.

FIG. 2 is an exploded perspective view of an example immersion cooling enclosure suitable for the computing facility of FIG. 1 in accordance with embodiments of the disclosed technology.

FIGS. 3A-3C are schematic cross-sectional views of the example immersion cooling enclosure during certain stages of operation in accordance with additional embodiments of the disclosed technology.

FIG. 4 is a schematic cross-sectional view of an example immersion cooling enclosure having automatic level control in accordance with additional embodiments of the disclosed technology.

FIG. 5 is a schematic cross-sectional view of an example immersion cooling enclosure having multiple level sensors in accordance with additional embodiments of the disclosed technology.

FIG. 6 is a flowchart illustrating a process of maintaining a server housed in an example immersion cooling enclosure configured in accordance with embodiments of the disclosed technology.

### DETAILED DESCRIPTION

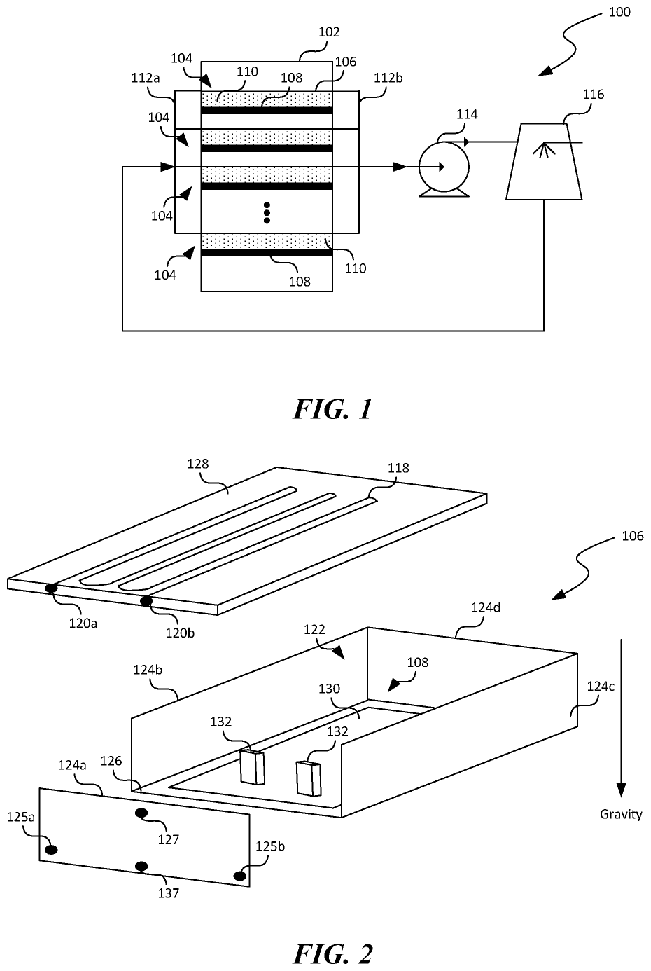

Certain embodiments of computing facilities, systems, devices, components, modules, and processes for rack mountable immersion cooling enclosures are described below. In the following description, specific details of components are included to provide a thorough understanding of certain embodiments of the disclosed technology. A person skilled in the relevant art can also understand that the disclosed technology may have additional embodiments or may be practiced without several of the details of the embodiments described below with reference to FIGS. 1-6.

As used herein, the term an “immersion server enclosure” generally refers to a housing configured to accommodate a server or other suitable types of computing device submerged in a dielectric coolant inside the housing during operation of the server. A “dielectric coolant” generally refers to a liquid that is thermally conductive but dielectric. Example dielectrics coolants can include mineral-oils or synthetic chemicals. Such a dielectric coolant can have a dielectric constant that is generally similar to that of ambient air (e.g., within 100%). For example, a dielectric coolant provided by 3M (Electronic Liquid FC-3284) has a dielectric constant of 1.86 while that of ambient air at 25° C. is about 1.0. In certain implementations, a dielectric coolant can have a boiling point low enough to absorb heat from operating electronic components (e.g., CPUs, GPUs, etc.). For instance, Electronic Liquid FC-3284 provided by 3M has a boiling point of 50° C. at 1 atmosphere pressure.

Immersion cooling of servers can have many advantages when compared to air cooling. For example, immersion cooling can be more thermodynamically efficient due to higher heat transfer coefficients. However, current designs of immersion cooling enclosures may not be suitable for retrofitting existing datacenters or other suitable computing facilities. For example, one design of an immersion cooling enclosure includes an elongated container (e.g., a 10-foot long container commonly referred to as a “tank”) housing multiple server blades mounted vertically in the tank. Retrofitting tank-type immersion cooling enclosures into support structures of an existing datacenter may be difficult or even impossible. In addition, such a tank design can incur high operating costs due to loss of a dielectric coolant used in the tank due to leakage, pressure control, maintenance, or other reasons during operation.

Several embodiments of the disclosed technology can address at least some of the drawbacks of the tank design by implementing a server-level immersion cooling enclosure. In certain embodiments, the immersion cooling enclosure can be configured to accommodate a single server blade. As such, a spacing between walls of the immersion cooling enclosure can be reduced when compared to tank type design. In addition, pressure control, fluid expansion, and dielectric coolant condensing can all be server-level serviceable, and thus reducing large scale downtime, as described in more detail below with reference to FIGS. 1-6.

FIG. 1 is a schematic diagram of a computing facility 100 having server assemblies 104 with immersion cooling enclosures 106 configured in accordance with embodiments of the disclosed technology. As shown in FIG. 1, the computing facility 100 can include a support structure 102 in which multiple server assemblies 104 are installed. The computing facility 100 can also include a circulation pump 114 and a cooling tower 116 operatively coupled to the server assemblies 104 via an inlet manifold 112a and an outlet manifold 112b. Even though only one support structure 102 is shown in FIG. 1 for illustration purposes, in other embodiments, the computing facility 100 can include multiple support structures 102 (not shown), multiple groups of support structures 102, and/or other suitable components.

The support structure 102 can include any suitable types of structures in which the server assemblies 104 can be installed. In one example, the support structure 102 can include a rack, e.g., a 19-inch for mounting multiple servers provided by Dell Corporation of Austin, Tex. In another example, the support structure 102 can include a drawer, a shelf, a cabinet, or other suitable types of frame. Though not shown in FIG. 1, in certain implementations, the support structure 102 can also house a fan, one or more intercoolers, and/or other suitable mechanical/electrical components.

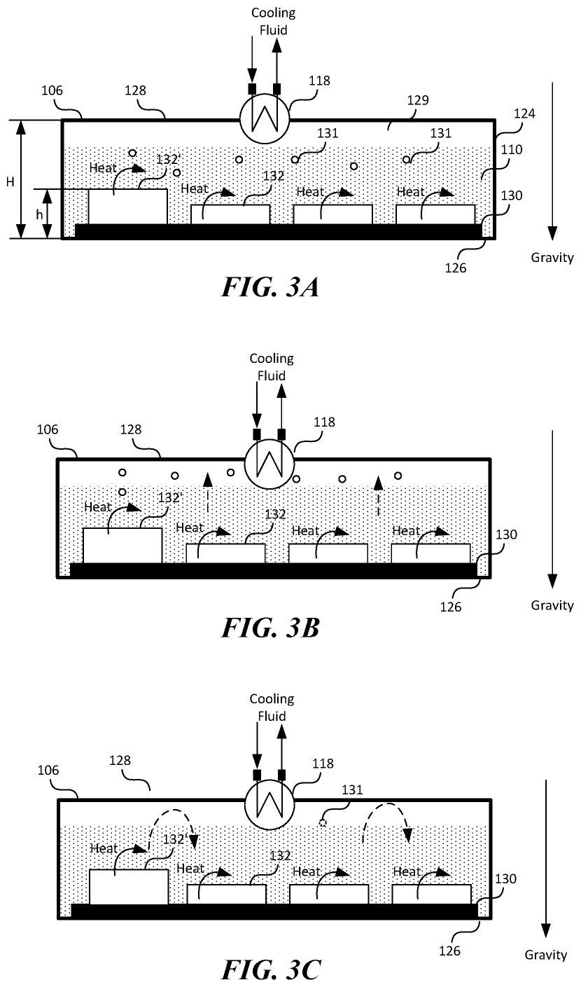

As shown in FIG. 1, the server assemblies 104 can individually include a server or server blade 108 (shown as a black rectangle) submerged in a dielectric coolant 110. The server assemblies 104 can also include a heat exchanger 118 (shown in FIG. 2) configured to receive a cooling fluid (e.g., cooling water or other suitable types of coolant) from the inlet manifold 112a and discharge heated cooling fluid through the outlet manifold 112b. In certain embodiments, the heat exchanger 118 can be attached to a top wall 128 (shown in FIG. 2) of the corresponding immersion cooling enclosure 106. In other embodiments, the heat exchanger 118 can be embedded or otherwise incorporated into the top wall 128. Example configurations of the server assemblies 104 are described in more detail below with reference to FIGS. 2-3C.

The circulation pump 114 can be configured to receive cooling fluid from the server assemblies 104 via the outlet manifold 112b and forward the received cooling fluid to the cooling tower 116. The cooling tower 116 can then remove heat from the cooling fluid and provide the cooling fluid to the server assemblies 104 via the inlet manifold 112a. The circulation pump 114 can include a centrifugal pump, a piston pump, or other suitable types of pump. Though particular configuration for cooling fluid circulation and cooling is shown in FIG. 1, in other embodiments, the computing facility 100 can also include additional and/or different components. For example, the computing facility 100 can include a chiller, one or more heat exchangers (not shown), and/or other suitable mechanical components.

In operation, components of the server blades 108 in the individual server assemblies 104 can consume power from a power source (not shown, e.g., an electrical grid) to execute suitable instructions to provide desired computing services. The dielectric coolant 110 can absorb the heat produced by the components during operation and eject the absorb heat into the cooling fluid flowing through the heat exchangers. In certain embodiments, the dielectric coolant 110 absorbs the heat produced by the servers via phase transition, i.e., evaporating a portion of the dielectric coolant into a vapor. In other embodiments, the dielectric coolant 110 can absorb the heat without a phase change. The circulation pump 114 then forwards the heated cooling fluid to the cooling tower 116 for discarding the heat to a heat sink (e.g., the atmosphere). The cooling fluid is then circulated back to the server assemblies 104 via the inlet manifold 112a.

FIG. 2 is an exploded perspective view of an example immersion cooling enclosure 106 suitable for the computing facility of FIG. 1 in accordance with embodiments of the disclosed technology. As shown in FIG. 2, the immersion cooling enclosure 106 can include a top wall 128, a bottom wall 126 opposite the top wall 128, and multiple sidewalls 124 (shown as first, second, third, and fourth sidewalls 124a-124d, respectively) between the top wall 128 and the bottom wall 126. As shown in FIG. 2, the top wall 128, the bottom wall 126, and the sidewalls 124 can form a housing having an interior space 122 in which a dielectric coolant 110 (shown in FIG. 1) can be contained. The bottom wall 130 can also be configured to mount a server blade 108 having a printed circuit board 130 carrying one or more heat producing components 132. As used herein, the term “heat producing components” can include any electronic components that produce heat during operation. Examples of heat producing components 132 can include CPUs, GPUs, SSDs, memory chips, etc.

As shown in FIG. 2, the first sidewall 124a can also include one or more access ports to the interior space 122 of the immersion cooling enclosure 106. For example, the first sidewall 124a can include a purge port 125a for purging the dielectric coolant 110 from the interior space 122 and a refill port 125b for filling the interior space 122 with the dielectric coolant 110. The first sidewall 124b can also include a pressure control port 127 for controlling a pressure in the interior space 122 and a diagnostic port 137. In certain implementations, the diagnostic port 137 can be configured to allow access to various components of the server blade 108. O-rings or other suitable types of seals may be used to seal the diagnostic port 137 against leakage of the dielectric coolant 110. In other implementations, the diagnostic port 137 can also be configured to allow sampling of the dielectric coolant 110 in the interior space 122. In further implementations, the purge port 125a or other suitable types of port may be used for sampling the dielectric coolant 110. Example configurations for performing pressure control are described in more detail below with reference to FIG. 5. In other embodiments, one or more of the sidewalls 124 can also include additional ports (not shown) for mounting level sensors, pressure sensors, temperature sensors, and/or other suitable types of sensors. Even though the example ports 125a, 125b, and 127 are shown as being located on the first sidewall 124a in FIG. 2 for illustration purposes, in other embodiments, one or more of the foregoing ports 125a, 125b, and 127 can be located on any one of the top wall 128, the bottom wall 130, or other sidewalls 124.

Also shown in FIG. 2, the top wall 128 can incorporate a heat exchanger 118. In the illustrated example, the heat exchanger 118 includes a coil attached to or embedded in the top wall 128. The heat exchanger 118 can have an inlet 120a coupled to the inlet manifold 112a (FIG. 1) and an outlet 120b coupled to the outlet manifold 112b. Though the heat exchanger 118 is shown in FIG. 1 as a coil, in other embodiments, the top wall 128 can also incorporate the heat exchanger 118 in other suitable manners. For example, the top wall 128 can include an internal space divided by multiple baffles to create a tortuous flow path for the cooling fluid. In other examples, the top wall 128 can also include a thermoelectric cooler (e.g., a Peltier cooler) and/or other suitable types of cooling elements.

FIGS. 3A-3C are schematic cross-sectional views of a server assembly 104 with an example immersion cooling enclosure 104 during certain stages of operation in accordance with additional embodiments of the disclosed technology. As shown in FIG. 3A, the printed circuit board 130 can be mounted directly to the bottom wall 126 of the immersion cooling enclosure 106 via adhesives, fasteners, pressure fitting, or other suitable mounting techniques. The heat producing components 132 can be carried on the printed circuit board 130 and can have different heights extending from the bottom wall 126 toward the top wall 128. For example, the heat producing component 132′ can have a height h that is largest among all the heat producing components 132. In accordance with embodiments of the disclosed technology, the printed circuit board 130 can be oriented generally perpendicular (e.g., within +/−10°) to gravity when installed into the support structure 102. A distance between the top wall and the bottom wall (referred to as “spacing” and represented in FIG. 3A as “H”) can be just sufficient to accommodate the largest height h of the heat producing component carried on the printed circuit board 130. For example, the spacing H can be about 105% of a largest height h extending from the bottom wall toward the top wall. In other examples, the spacing can be 110%, 115%, 120%, or other suitable values not exceeding 150%, 200%, or 250%.

Also shown in FIG. 3A, the server assembly 104 can have a vapor gap 129 above the dielectric coolant 110. In other implementations, the server assembly 104 may not have the vapor gap 129. Instead, the immersion cooling enclosure 106 can be substantially filled with the dielectric coolant 110 such that the dielectric coolant 110 is in contact with both the top wall 128 and the bottom wall 126. During operation, the heat producing components 132 can consume power to execute instructions to provide suitable computing services. The dielectric coolant 110 can absorb the produced heat by evaporating a portion of the dielectric coolant 110 into a vapor 131. As such, the dielectric coolant 110 becomes a two-phase fluid having a liquid phase and a vapor 131 (represented in FIG. 3A as bubbles) in the liquid phase.

As shown in FIG. 3B, due to gravity, the bubbles 131 rise toward the vapor gap 129 and come in contact with the heat exchanger 118 of the top wall 128. The cooling fluid flowing through the heat exchanger 118 can then condense the vapor 131 into liquid droplets 133. The liquid droplets 133 then fall back down to the liquid phase of the dielectric coolant 110. Thus, heat produced by the heat producing components 132 can be removed by the circulation of the two-phase dielectric coolant 110 described above.

Several embodiments of the immersion cooling enclosure have certain advantages when compared to the tank design of immersion cooling. For example, several server assemblies 104 housed in individual immersion cooling enclosures 106 can be co-located with other air-cooled server blades in a single rack, drawer, etc. Also, pressure control, fluid expansion, and dielectric coolant 110 condensing can all be server-level serviceable, and thus reducing large scale downtime. In contrast, when one server blade fails in a tank, all other server blades must be shut down before the failed server blade can be serviced. In addition, the immersion cooling enclosure 106 can be configured to contain a small volume of the dielectric coolant 110. As such, risks of excessive pressure buildup can be at least reduced when compared to a larger and deeper tank. Thus, risks of catastrophic tank-level failure may be reduced. In another example, the immersion cooling enclosures 106 can be pre-filled on-site for quick swapping or left empty for ease of transport. Such a flexibility is not available to the tank design.

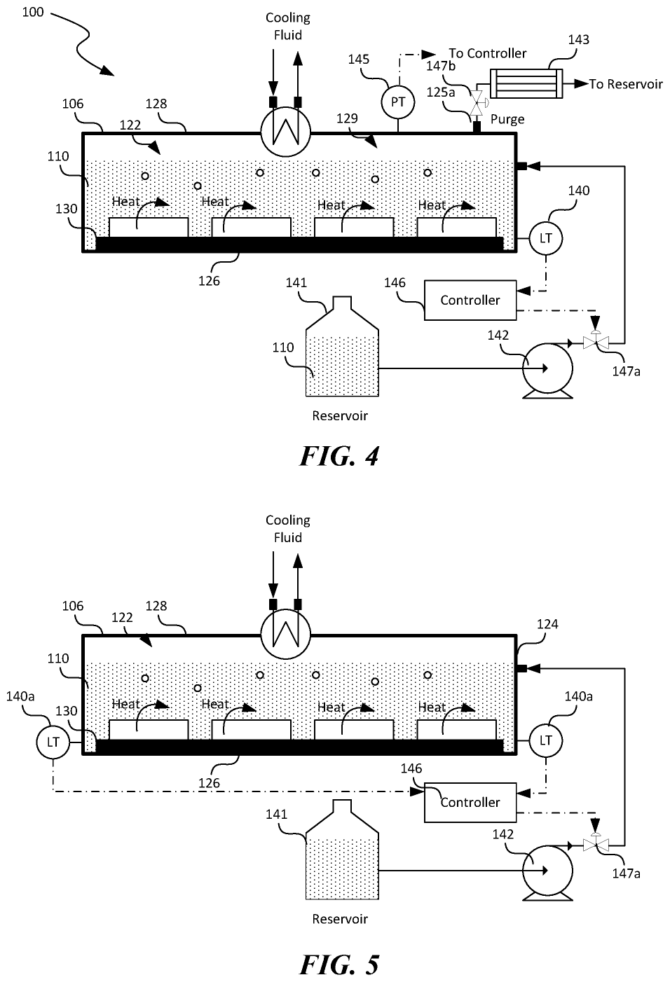

FIG. 4 is a schematic cross-sectional view of an example immersion cooling enclosure 106 having automatic level control in accordance with additional embodiments of the disclosed technology. As shown in FIG. 4, the computing facility 100 can include a level sensor 140 (shown in FIG. 4 as a level transmitter) operatively coupled to a controller 146, a dielectric coolant pump 142, a dielectric coolant valve 147a, and a reservoir 141 for storing the dielectric coolant 110. The controller 146 can include a programmable logic controller or other suitable types of controller. In operation, the level sensor 140 can be configured to provide a measured level of the dielectric coolant 110 in the interior space 122 of the immersion cooling enclosure 106. The controller 146 can then compare the measured level to a level setpoint. In response to determining that the measured level is below the level setpoint, the controller 146 can be configured to instruct the dielectric coolant valve 147a to open, and thus allowing additional dielectric coolant 110 be fed into the immersion cooing enclosure 106.

As shown in FIG. 4, the immersion cooling enclosure 106 can also incorporate pressure control. For example, a pressure sensor 145 (shown as a pressure transmitter in FIG. 4) can be configured to measure a pressure in the vapor gap 129. The pressure sensor 145 can then transmit the measured pressure to the controller 146. The controller 146 can then compare the measured pressure to a pressure setpoint. In response to determining that the measured pressure exceeds the pressure setpoint, the controller 146 can be configured to instruct the purge valve 147b to open by purging a portion of vapor phase dielectric coolant 110 to a condenser 143. The condenser 143 can include a heat exchanger, a mechanical chiller, or other suitable device. The condensed dielectric coolant 110 can then be returned to the reservoir 141.

FIG. 5 is a schematic cross-sectional view of an example immersion cooling enclosure 106 having multiple level sensors 140 in accordance with additional embodiments of the disclosed technology. As shown in FIG. 5, the immersion cooling enclosure 106 can include a first level sensor 140a and a second level sensor 140b mounted on opposite sidewalls 124 of the immersion cooling enclosure 106. In operation, the first and second level sensors 140a and 140b can be configured to provide measured levels of the dielectric coolant 110 in the immersion cooing enclosure 106. The controller 146 can be configured to compare the measured levels from the first and second level sensors 140a and 140b. In response to determining that a difference between the measured levels exceeds a threshold, the controller 146 ca be configured to raise an alarm to, for instance, an operator. The alarm can indicate to the operator that the immersion cooling enclosure 106 is tilted and/or the level of the dielectric coolant 110 is low in the immersion cooling enclosure 106.

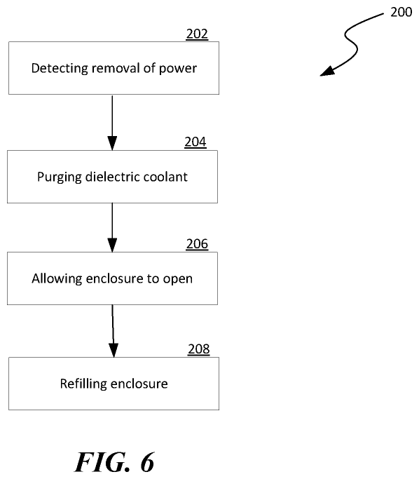

FIG. 6 is a flowchart illustrating a process of maintaining a server housed in an example immersion cooling enclosure 106 configured in accordance with embodiments of the disclosed technology. As shown in FIG. 6, the process 200 can include detecting removal of power from the server housed in the immersion cooing enclosure 106 at stage 202. The process 200 can then include purging (e.g., with nitrogen) the dielectric coolant from the immersion cooling enclosure 106 at stage 204. Upon completion of purging the immersion cooing enclosure 106, the process 200 can include allowing an operator to open the immersion cooing enclosure 106 and perform various suitable operations, such as replacing components of the server. The process 200 can then include refilling the enclosure before power can be applied to the server at stage 208.

From the foregoing, it will be appreciated that specific embodiments of the disclosure have been described herein for purposes of illustration, but that various modifications may be made without deviating from the disclosure. In addition, many of the elements of one embodiment may be combined with other embodiments in addition to or in lieu of the elements of the other embodiments. Accordingly, the technology is not limited except as by the appended claims.

1. A rack mountable immersion cooling enclosure, comprising:
a first wall;
a second wall spaced apart from and opposite the first wall; and
multiple sidewalls between the first wall and the second wall, the first wall, the second wall, and the sidewalls surrounding an interior space, wherein:
the first wall having a heat exchanger attached to or embedded in the first wall, the heat exchanger including a coil embedded in the first wall having a coolant inlet and a coolant outlet at one end of the first wall and being configured to remove heat from the interior space of the immersion cooling enclosure via a coolant circulating through the coil from the coolant inlet to the coolant outlet;
the second wall carrying a printed circuit board in the interior space, the printed circuit board having thereon one or more heat producing components individually having a height extending from the second wall toward the first wall in the interior space of the rack mountable immersion cooling enclosure; and
a distance between the first wall and the second wall is less than 150% of one of the largest heights of the heat producing components on the printed circuit board.

2. The rack mountable immersion cooling enclosure of claim 1, further comprising:
a dielectric coolant in the interior space of the rack mountable immersion cooling enclosure, the dielectric coolant being spaced apart from the first wall by a vapor gap; and
the one or more heat producing components on the printed circuit board are submerged in the dielectric coolant in the interior space of the rack mountable immersion cooling enclosure.

3. The rack mountable immersion cooling enclosure of claim 1, further comprising:
a dielectric coolant in the interior space of the rack mountable immersion cooling enclosure, the dielectric coolant being in contact with both the first wall and the second wall; and
the one or more heat producing components on the printed circuit board are submerged in the dielectric coolant in the interior space of the rack mountable immersion cooling enclosure.

4. The rack mountable immersion cooling enclosure of claim 1 wherein the heat exchanger of the first wall includes a coil attached to a top surface, a bottom surface opposite the top surface, or embedded inside the first wall.

5. The rack mountable immersion cooling enclosure of claim 1 wherein the heat exchanger of the first wall includes an internal space of the first wall having one or more baffles that create a tortuous path inside the internal space of the first wall.

6. The rack mountable immersion cooling enclosure of claim 1, further comprising:
a pressure sensor configured to detect a pressure in the interior space of the rack mountable immersion cooling enclosure;
a purge valve connected to a purge port on one of the first wall, the second wall, or the sidewalls and
a controller operatively coupled to the pressure sensor and the purge valve, the controller being configured to actuate the purge valve in response to a signal from the pressure sensor that the pressure of the interior space exceeds a threshold.

7. The rack mountable immersion cooling enclosure of claim 1, further comprising:
a dielectric coolant in the interior space of the rack mountable immersion cooling enclosure;
a level sensor configured to measure a fluid level in the interior space of the rack mountable immersion cooling enclosure;
a refill valve connected to a refill port on one of the first wall, the second wall, or the sidewalls and a reservoir of the dielectric coolant; and
a controller operatively coupled to the level sensor and the refill valve, the controller being configured to actuate the refill valve in response to a signal from the level sensor that the level of the dielectric coolant in the interior space is below a threshold.

8. The rack mountable immersion cooling enclosure of claim 1, further comprising:
a dielectric coolant in the interior space of the rack mountable immersion cooling enclosure;
a level sensor configured to measure a fluid level in the interior space of the rack mountable immersion cooling enclosure; and
a controller operatively coupled to the level sensor, the controller being configured to indicate a leakage of the dielectric coolant when a change in the fluid level measured by the level sensor exceeds a threshold.

9. The rack mountable immersion cooling enclosure of claim 1, further comprising:
a dielectric coolant in the interior space of the rack mountable immersion cooling enclosure;
first and second level sensors individually configured to measure a fluid level in the interior space of the rack mountable immersion cooling enclosure, one of the first and second level sensors being mounted at one of the first wall, second wall, or the sidewalls while the other of the first or second level sensors being mounted on a different one of the first wall, second wall, or the sidewalls; and
a controller operatively coupled to the first and second level sensors, the controller being configured to raise an alarm when a difference between fluid levels measured by the first and second level sensor exceeds a threshold.

10. A computing facility, comprising:
multiple immersion cooling enclosures individually having:
a first wall;
a second wall spaced apart from and opposite the first wall; and
multiple sidewalls between the first wall and the second wall, the first wall, the second wall, and the sidewalls surrounding an interior space, wherein:
the first wall having a heat exchanger attached to or embedded in the first wall, the heat exchanger including a coil embedded in the first wall having a coolant inlet and a coolant outlet at one end of the first wall and being configured to remove heat from the interior space of the immersion cooling enclosure via a coolant circulating through the coil from the coolant inlet to the coolant outlet;
the second wall carrying a printed circuit board in the interior space, the printed circuit board having thereon one or more heat producing components individually having a height extending from the second wall toward the first wall in the interior space of the immersion cooling enclosure; and
a distance between the first wall and the second wall is less than 150% of one of the largest heights of the heat producing components on the printed circuit board; and
a manifold operatively coupled to the heat exchangers of the multiple immersion cooling enclosures, the manifold being coupled to a source of cooling fluid.

11. The computing facility of claim 10 wherein the immersion cooling enclosures individually include:
a dielectric coolant in the interior space of the rack mountable immersion cooling enclosure, the dielectric coolant being spaced apart from the first wall by a vapor gap; and
the one or more heat producing components on the printed circuit board are submerged in the dielectric coolant in the interior space of the rack mountable immersion cooling enclosure.

12. The computing facility of claim 10 wherein the immersion cooling enclosures individually further include:
a dielectric coolant in the interior space of the rack mountable immersion cooling enclosure, the dielectric coolant being in contact with both the first wall and the second wall; and
the one or more heat producing components on the printed circuit board are submerged in the dielectric coolant in the interior space of the rack mountable immersion cooling enclosure.

13. The computing facility of claim 10 wherein the heat exchanger of the first wall includes a coil attached to a top surface, a bottom surface opposite the top surface, or embedded inside the first wall.

14. The computing facility of claim 10 wherein the heat exchanger of the first wall includes an internal space of the first wall having one or more baffles that create a tortuous path inside the internal space of the first wall.

15. The computing facility of claim 10 wherein the immersion cooling enclosures individually further include:
a pressure sensor configured to detect a pressure in the interior space of the rack mountable immersion cooling enclosure;
a purge valve connected to a purge port on one of the first wall, the second wall, or the sidewalls and
a controller operatively coupled to the pressure sensor and the purge valve, the controller being configured to actuate the purge valve in response to a signal from the pressure sensor that the pressure of the interior space exceeds a threshold.

16. The computing facility of claim 10 wherein the immersion cooling enclosures individually further include:
a dielectric coolant in the interior space of the rack mountable immersion cooling enclosure;
a level sensor configured to measure a fluid level in the interior space of the rack mountable immersion cooling enclosure;
a refill valve connected to a refill port on one of the first wall, the second wall, or the sidewalls and a reservoir of the dielectric coolant; and
a controller operatively coupled to the level sensor and the refill valve, the controller being configured to actuate the refill valve in response to a signal from the level sensor that the level of the dielectric coolant in the interior space is below a threshold.

17. The computing facility of claim 10 wherein the immersion cooling enclosures individually further include:
a dielectric coolant in the interior space of the rack mountable immersion cooling enclosure;
a level sensor configured to measure a fluid level in the interior space of the rack mountable immersion cooling enclosure; and
a controller operatively coupled to the level sensor, the controller being configured to indicate a leakage of the dielectric coolant when a change in the fluid level measured by the level sensor exceeds a threshold.

18-20. (canceled)
